(19) United States
(12) Patent Application Publication
(10) Pub. No.: US 2021/0310975 A1
(43) Pub. Date: Oct. 7, 2021

(54) IN-SITU OPTICAL AND ELECTROCHEMICAL ANALYSIS METHOD AND BATTERY CELL SECTION MEASUREMENT MODULE THEREFOR

(71) Applicants: KOREA BASIC SCIENCE INSTITUTE, Daejeon (KR); THE INDUSTRY & ACADEMIC COOPERATION IN CHUNGNAM NATIONAL UNIVERSITY (IAC), Daejeon (KR); KOREA RESEARCH INSTITUTE OF STANDARDS AND SCIENCE, Daejeon (KR)

(72) Inventors: Joonhee MOON, Daejeon (KR); Cheolho JEON, Sejong (KR); Jouhahn LEE, Daejeon (KR); Kyoung Soon CHOI, Daejeon (KR); Chunjoong KIM, Daejeon (KR); Jae Yong SONG, Daejeon (KR); Hosun SHIN, Daejeon (KR); Sun Hwa PARK, Seoul (KR)

(73) Assignees: KOREA BASIC SCIENCE INSTITUTE, Daejeon (KR); THE INDUSTRY & ACADEMIC COOPERATION IN CHUNGNAM NATIONAL UNIVERSITY (IAC), Daejeon (KR); KOREA RESEARCH INSTITUTE OF STANDARDS AND SCIENCE, Daejeon (KR)

(21) Appl. No.: 17/352,814

(22) Filed: Jun. 21, 2021

Related U.S. Application Data
(63) Continuation of application No. PCT/KR2018/016377, filed on Dec. 20, 2018.

(30) Foreign Application Priority Data
Dec. 19, 2018 (KR) 10-2018-0165534

(51) Int. Cl. G01N 27/27; H01M 10/42; H01M 10/48; G01N 21/65; G01N 27/403

(52) U.S. Cl. CPC G01N 27/27; H01M 10/4285; G01N 27/403; G01N 21/65; H01M 10/48

(57) ABSTRACT

A battery cell measurement module for in-situ optical and electrochemical analysis includes a lower housing including a battery cell accommodation space therein, an upper cover that is detachably attached to the lower housing and provided with a transparent window, and a battery cell block that is arranged in the battery cell accommodation space. The battery cell block includes a first electrode base portion, a second electrode base portion, and a battery stack arranged between the first electrode base portion and the second electrode base portion. The first electrode base portion, the battery stack, and the second electrode base portion are sequentially arranged in a first direction parallel to an upper surface of the transparent window such that a thickness direction of the battery stack is arranged parallel to the upper surface of the transparent window.

### CROSS-REFERENCE TO RELATED APPLICATIONS

The present application is a continuation application of International Application No. PCT/KR2018/016377, filed Dec. 20, 2018, which claims the benefit of and priority to Korean Application No. 10-2018-0165534, filed Dec. 19, 2018. The above-referenced applications are hereby incorporated herein by reference in their entirety.

### TECHNICAL FIELD

The present disclosure relates to an in-situ optical and electrochemical analysis method and a battery cell measurement module therefor, and more particularly, to a battery cell measurement module capable of electrochemical behavior analysis via the cross section of the inside of a battery cell during charging and discharging, and an in-situ optical and electrochemical analysis method using same.

### BACKGROUND

Recently, as the demand for using lithium-ion batteries in various application fields such as small mobile devices and electric vehicles increases, there is a growing need to optimize the performance of lithium-ion batteries according to various requirements for various application fields. In particular, studies on electrochemical properties of new cathode active material candidates and anode active material candidates having large capacity and low cost have been actively conducted. However, the relationship between phase change characteristics and electrochemical performance of some of new cathode active materials and anode active materials according to charging and discharging has not been clearly defined. Therefore, it is difficult to improve the performance of these candidate materials and commercialize these candidate materials.

### SUMMARY

According to an aspect of the present disclosure, a battery cell measurement module for in-situ optical and electrochemical analysis may include: a lower housing including a battery cell accommodation space therein; an upper cover which is detachably attached to the lower housing and provided with a transparent window; and a battery cell block which is arranged in the battery cell accommodation space and includes a first electrode base portion, a second electrode base portion, and a battery stack arranged between the first electrode base portion and the second electrode base portion, wherein the first electrode base portion, the battery stack, and the second electrode base portion are sequentially arranged in a first direction parallel to an upper surface of the transparent window such that a thickness direction of the battery stack is arranged parallel to the upper surface of the transparent window.

In an example embodiment, the battery stack may include: a cathode current collector having a cathode active material attached thereto; an anode current collector having an anode active material attached thereto; and a separator arranged between the cathode active material and the anode active material, wherein the battery cell block is arranged such that the cathode current collector, the cathode active material, the separator, the anode active material, and the anode current collector all face the transparent window.

In an example embodiment, the cathode active material may have a first thickness in a direction perpendicular to an upper surface of the cathode current collector, the anode active material may have a second thickness in a direction perpendicular to an upper surface of the anode current collector, and the battery cell block may be arranged such that the entire first thickness of the cathode active material and the entire second thickness of the anode active material are observed via the transparent window.

In an example embodiment, the battery cell measurement module may further include a third electrode base portion which is arranged in the battery cell accommodation space, and the third electrode base is arranged on one side of the first electrode base portion, the battery stack, and the second electrode base portion to be located adjacent to all of the first electrode base portion, the battery stack, and the second electrode base portion, wherein the third electrode base portion operates as a reference electrode that provides a reference voltage for the cathode active material and the anode active material.

In an example embodiment, the lower housing may further include a supply line opening configured to supply an electrolyte from an external supply portion into the battery cell accommodation space, and the first electrode base portion may be configured to include at least one of: a plurality of openings which pass through the first electrode base portion; and a trench which extends along the entire length of the first electrode base portion in a direction parallel to an upper surface of the first electrode base portion, and allow the electrolyte to reach the battery stack via at least one of the plurality of openings and the trench.

According to another aspect of the present disclosure, an in-situ optical and electrochemical analysis method using a battery cell measurement module may include: sequentially arranging a first electrode base portion, a battery stack, and a second electrode base portion included in a battery cell block, in a first direction parallel to the upper surface of a transparent window, and performing charging and discharging operations on the battery cell measurement module; and performing, a plurality of times, a light measurement cycle on the battery cell measurement module, wherein the light measurement cycle includes: irradiating first light to a first portion of the battery stack observed via the transparent window; detecting the first light scattered from the battery stack; irradiating, to the first portion of the battery stack observed via the transparent window, second light having a second wavelength that is different than a first wavelength of the first light; and detecting the second light scattered from the battery stack, the battery cell measurement module including: a lower housing including a battery cell accommodation space therein; an upper cover which is detachably attached to the lower housing and provided with the transparent window; and the battery cell block arranged in the battery cell accommodation space.

In an example embodiment, the irradiating of the second light may include continuously irradiating the second light by a first scan width in a thickness direction of the battery stack observed via the transparent window.

In an example embodiment, the battery stack may include: a cathode current collector having a cathode active material attached thereto; an anode current collector having an anode active material attached thereto; and a separator arranged between the cathode active material and the anode active material, wherein the battery cell block is arranged such that the cathode current collector, the cathode active material, the separator, the anode active material, and the anode current collector all face the transparent window, and the irradiating of the second light includes at least one of: continuously irradiating the second light by the first scan width in a thickness direction of the cathode active material observed via the transparent window; and continuously irradiating the second light by the first scan width in a thickness direction of the anode active material observed via the transparent window.

### BRIEF DESCRIPTION OF DRAWINGS

FIG. 1 is a schematic view illustrating an in-situ optical measurement system according to example embodiments.

FIG. 2 is a plan view illustrating a battery cell measurement module according to example embodiments.

FIG. 3 is a cross-sectional view taken along line III-III′ of FIG. 2.

FIG. 4 is a plan view illustrating a battery cell measurement module according to example embodiments.

FIG. 5 is a plan view illustrating a battery cell measurement module according to example embodiments.

FIG. 6 is a plan view illustrating a battery cell measurement module according to example embodiments.

FIG. 7 is a perspective view illustrating a first electrode base portion included in a battery cell measurement module.

FIG. 8 is a perspective view illustrating a first electrode base portion included in a battery cell measurement module.

FIG. 9 is a flowchart illustrating an in-situ optical and electrochemical analysis method according to example embodiments.

FIG. 10 is a graph illustrating a voltage profile in one-time charging and one-time discharging for a DMPZ cathode active material.

FIG. 11 illustrates optical images of a cathode active material at different voltages during one-time charging.

FIGS. 12A and 12B are Raman shift graphs at different voltages during one-time charging and one-time discharging in a first portion and a second portion of a cathode active material.

FIG. 13A illustrates optical images of a cathode active material according to voltages in each of a first charging cycle and a first discharging cycle.

FIG. 13B illustrates optical images of a cathode active material according to voltages in a second charging cycle.

### DETAILED DESCRIPTION OF EMBODIMENTS

Provided is a battery cell measurement module capable of precise analysis of an electrochemical behavior via the cross section of the inside of a battery cell during charging and discharging.

Provided is an in-situ optical and electrochemical analysis method capable of precise analysis of an electrochemical behavior via the cross section of the inside of a battery cell during charging and discharging by using a battery cell measurement module.

In a battery cell measurement module according to the present disclosure, a first electrode base portion, a battery stack, and a second electrode base portion may be sequentially arranged in a first direction parallel to the upper surface of a transparent window such that a thickness direction of the battery stack accommodated in a battery cell accommodation space of a lower housing is arranged parallel to the upper surface of the transparent window of an upper cover. While charging and discharging are performed on the battery cell measurement module, optical images of thickness direction cross sections of a cathode active material, a separator, and an anode active material in the battery stack may be measured, and composition analysis of the thickness direction cross sections may be performed via a Raman spectrometer. For example, during a charging step and a discharging step for a cathode active material or an anode active material, interfacial movement at each potential, precipitation and dissolution of the active material, and a change in thickness of the active material may be observed via optical images. Simultaneously with the observation of the optical images, material energy analysis, crystal structure analysis, phase change analysis, and/or composition analysis within an active material may be performed, via a Raman spectrometer, at at least one fixed position inside the active material or fixed positions corresponding to a first scan width that continuously extends. Therefore, electrochemical behaviors and reaction rates of new cathode active materials where electrochemical behaviors are not clearly identified, and new anode active materials may be precisely observed and analyzed.

In order to fully understand the structure and effect of the present disclosure, example embodiments of the present disclosure will be described with reference to the accompanying drawings. The present disclosure may, however, be embodied in many different forms and should not be construed as being limited to the embodiments set forth herein. These embodiments are provided so that the present disclosure will be thorough and complete, and will fully convey the concept of the disclosure to those skilled in the art. In the drawings, the thicknesses or sizes of elements are enlarged more than actual thicknesses or sizes for convenience of description, and the proportion of each element may be exaggerated or reduced.

It will be understood that when an element is referred to as being “on,” “connected to” or “coupled to” another element, it may be directly on, connected or coupled to other element or intervening elements may be present. In contrast, when an element is referred to being “directly on,” “directly connected to” or “directly coupled to” another element, there are no intervening elements present. Other words used to describe the relationship between elements should be interpreted in a like fashion (e.g., “between,” versus “directly between,” “adjacent,” versus “directly adjacent,” etc.).

While such terms as “first,” “second,” etc., may be used to describe various elements, such elements must not be limited to the above terms. The above terms are used only to distinguish one element from another. For example, a first element may be termed a second element, and, similarly, a second element may be termed a first element, without departing from the scope of the preset disclosure.

An expression used in the singular encompasses the expression of the plural, unless it has a clearly different meaning in the context. It will be understood that the terms “comprises,” “comprising,” “includes,” “including,” “have,” “having,” etc. when used herein, specify the presence of stated features, integers, steps, operations, elements, components, and/or groups thereof, but do not preclude the presence or addition of one or more other features, integers, steps, operations, elements, components, and/or groups thereof.

Unless otherwise defined, all terms used herein have the same meanings as commonly understood by one of ordinary skill in the art to which example embodiments belong.

Hereinafter, the present disclosure will be described in detail by describing example embodiments of the present disclosure with reference to the accompanying drawings.

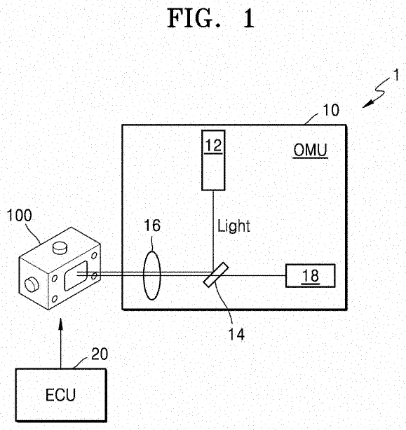

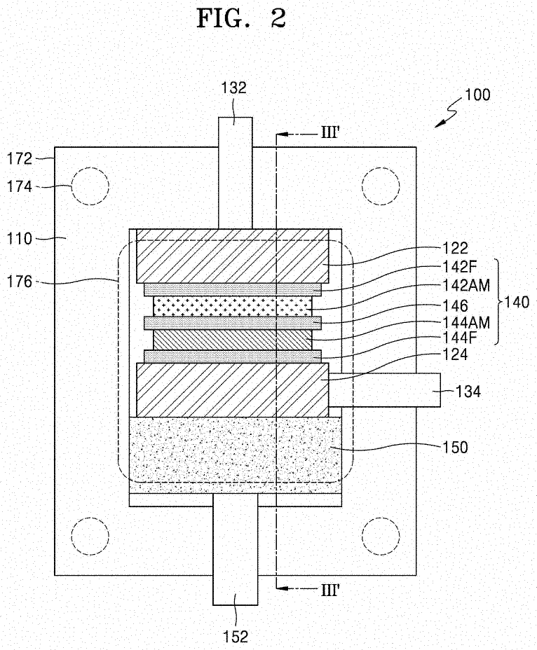

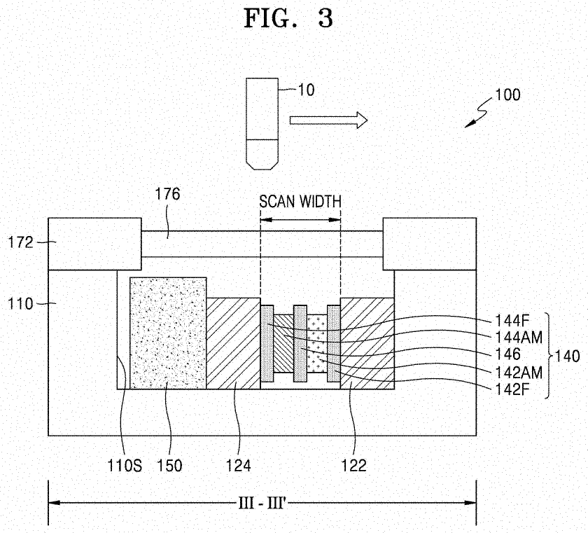

FIG. 1 is a schematic view illustrating an in-situ optical measurement system 1 according to example embodiments. FIG. 2 is a plan view illustrating a battery cell measurement module 100 according to example embodiments. FIG. 3 is a cross-sectional view taken along line III-III′ of FIG. 2.

Referring to FIGS. 1 through 3, the in-situ optical measurement system 1 may include an optical analysis unit (OMU) 10, an electrochemical analysis unit (ECU) 20, and the battery cell measurement module 100.

The optical analysis unit 10 may be configured as a measurement device capable of analyzing optical characteristics of a battery stack 140 included in the battery cell measurement module 100. In example embodiments, the optical analysis unit 10 may be configured to perform optical image analysis and Raman shift analysis. In other embodiments, the optical analysis unit 10 may include a plurality of analysis units capable of optical image analysis, Raman shift analysis, and photoluminescence (PL) characteristic analysis, respectively.

For example, the optical analysis unit 10 may include a Raman spectrometer capable of irradiating light to the battery stack 140 by using a laser as a light source, and receiving and detecting light reflected through the battery stack 140. Also, the optical analysis unit 10 may further include an optical microscope. The optical microscope may store image information of the battery stack 140 via a CCD camera (not shown) by irradiating light to the battery stack 140 and receiving light reflected through the battery stack 140.

For example, the optical analysis unit 10 may include a light source 12, a light splitter 14, a lens 16, and a detector 18. For example, the light source 12 may include a laser source, and a laser may be emitted from the light source 12. The light splitter 14 may reflect light emitted from the light source 12 to be incident on the lens 16. The light incident on the lens 16 may be incident on the battery stack 140 in the battery cell measurement module 100. Light scattered from the battery stack 140 may pass through the lens 16 and the light splitter 14 to be received by the detector 18. The detector 18 may include a camera or a spectrometer.

In example embodiments, an optical microscope may irradiate light to a measurement region of the battery cell measurement module 100 (i.e., a region indicated by a scan width in FIG. 3) to store an image of the measurement region. Also, a Raman spectrometer may irradiate light to a plurality of fixed measurement positions within the measurement region to acquire the results of Raman shift measurement from the plurality of fixed measurement positions. In addition, the Raman spectrometer may irradiate light to measurement positions continuously arranged along a measurement line having a first scan width within the measurement region to acquire the result of Raman shift measurement from the measurement line.

The electrochemical analysis unit 20 may be configured as a measurement device capable of analyzing the electrochemical performance of the battery stack 140 (refer to FIG. 2) included in the battery cell measurement module 100. For example, the electrochemical analysis unit 20 may be configured to be electrically connected to the battery stack 140 to adjust a voltage and current of the battery stack 140 or record voltage information and current information of the battery stack 140.

For example, the electrochemical analysis unit 20 may be configured to drive, a plurality of times, an electrochemical cycle including charging and discharging for the battery stack 140. In a charging cycle for the battery stack 140, a current may be applied to the battery stack 140 at a preset current rate, and a voltage of the battery stack 140 according to the application of the current may be measured and recorded. When the voltage of the battery stack 140 reaches a preset off voltage, a discharging cycle for the battery stack 140 may be initiated, and a voltage of the battery stack 140 through which a discharging current flows at a preset current rate may be measured and recorded.

The battery cell measurement module 100 may be configured to include a transparent window 176, irradiate light to the battery stack 140 via the transparent window 176, and detect light reflected from the battery stack 140. The battery cell measurement module 100 may be configured such that, within a measurement region observable via the transparent window 176 (i.e., a region indicated by a scan width), a cathode current collector 142F, a cathode active material 142AM, a separator 146, an anode active material 144AM, and an anode current collector 144F of the battery stack 140 may be sequentially arranged in a first direction (Y direction) parallel to the transparent window 176. In other words, a stack direction of the battery stack 140 may be arranged parallel to the transparent window 176. Accordingly, optical image analysis and Raman analysis may be easily performed on a region of interest from among the cathode current collector 142F, the cathode active material 142AM, the separator 146, the anode active material 144AM, and the anode current collector 144F of the battery stack 140. Also, the stack direction of the battery stack 140 may be arranged parallel to the transparent window 176. Accordingly, optical image analysis and Raman analysis may be easily performed on a plurality of fixed positions or a continuous measurement line within the measurement region by continuously scanning a region of a portion of the cathode current collector 142F, the cathode active material 142AM, the separator 146, the anode active material 144AM, and the anode current collector 144F of the battery stack 140.

According to example embodiments, while electrochemical characteristic analysis is performed on the battery stack 140 via the electrochemical analysis unit 20, image analysis and Raman analysis may be simultaneously performed on a portion of the battery stack 140 via the optical analysis unit 10. Accordingly, comprehensive analysis, such as identification of an electrochemical reaction of the active material occurring during charging and discharging for the cathode active material 142AM or the anode active material 144AM that is an object of interest, observation of a change in a crystalline phase or crystalline structure, analysis of a reaction rate in a local region, observation of interfacial movement of the active material, or observation of a change in local thickness of the active material, may be performed with respect to an electrochemical behavior of the battery stack 140.

In an existing in-situ electrochemical cell, a structure in which a cathode active material and an anode active material are stacked with a separator therebetween is arranged within a coin-type cell having an opening formed in the upper surface thereof, and merely the surface of the cathode active material is observed via the opening, or merely the surface of the anode active material is observed via the opening. In particular, the surface observable via the opening may be the surface arranged on the uppermost portion of the coin-type cell or the surface of an anode portion from which a corresponding cathode portion is removed (or the surface of the cathode portion from which the corresponding anode portion is removed). Accordingly, an electrochemical behavior of an active material on the surface observable via the opening may be significantly different from an electrochemical behavior occurring in an internal region of the coin-type cell, and thus, precise analysis of an electrochemical behavior may not be easily performed.

However, according to the present disclosure, as the cathode current collector 142F, the cathode active material 142AM, the separator 146, the anode active material 144AM, and the anode current collector 144F of the battery stack 140 are stacked in the battery cell measurement module 100 in a direction parallel to the transparent window 176, the cathode current collector 142F, the cathode active material 142AM, the separator 146, the anode active material 144AM, and the anode current collector 144F may be simultaneously observed or measured. In particular, a composition or image of a material at a fixed position may be continuously observed in a thickness direction of the cathode active material 142AM or a thickness direction of the anode active material 144AM, and movement and the like of an interface between the cathode active material 142AM and the cathode current collector 142F adjacent thereto or an interface between the anode active material 144AM and the anode current collector 144F adjacent thereto may be simultaneously observed. Accordingly, an electrochemical behavior of the battery stack 140 occurring in charging and discharging stages for the battery stack 140 may be precisely measured or analyzed.

Hereinafter, the detailed structure of the battery cell measurement module 100 will be described in detail with reference to FIGS. 2 and 3.

The battery cell measurement module 100 may include a lower housing 110 and an upper cover 172 detachably attached to the lower housing 110. The lower housing 110 may have therein a battery cell accommodation space 110S capable of accommodating the battery stack 140. The upper cover 172 may have the transparent window 176 via which the cross section of the battery stack 140 may be observed and may be attached to the lower housing 110 via cover fixing portions 174. In FIG. 2, for convenience of understanding, the upper cover 172, the cover fixing portions 174, and the transparent window 176 are shown by dotted lines.

The lower housing 110 may have the battery cell accommodation space 110S therein, and a battery cell block including the battery stack 140 may be arranged inside the battery cell accommodation space 110S. The lower housing 110 may include a metal or insulating material having rigidity. For example, the lower housing 110 may be formed of an SUS material to prevent corrosion but is not limited thereto.

The battery cell block may include a first electrode base portion 122, a second electrode base portion 124, and the battery stack 140 arranged between the first electrode base portion 122 and the second electrode base portion 124. The first electrode base portion 122, the battery stack 140, and the second electrode base portion 124 may be sequentially arranged in a first direction (Y direction) parallel to the upper surface of the transparent window 176. In other words, at least a portion of the first electrode base portion 122, a at least a portion of the battery stack 140, and at least a portion of the second electrode base portion 124 may be simultaneously observed via the transparent window 176.

A first electrode connection portion 132 may pass through the lower housing 110 to be electrically connected to the first electrode base portion 122. The first electrode connection portion 132 may be a connection terminal capable of supplying a current from the electrochemical analysis unit 20 to the battery stack 140 via the first electrode base portion 122. A second electrode connection portion 134 may pass through the lower housing 110 to be electrically connected to the second electrode base portion 124. The second electrode connection portion 134 may be a connection terminal capable of supplying a current from the electrochemical analysis unit 20 to the battery stack 140 via the second electrode base portion 124.

The battery stack 140 may include the cathode current collector 142F, the cathode active material 142AM, the separator 146, the anode active material 144AM, and the anode current collector 144F. The cathode current collector 142F may be in contact with the first electrode base portion 122, and the anode current collector 144F may be in contact with the second electrode base portion 124.

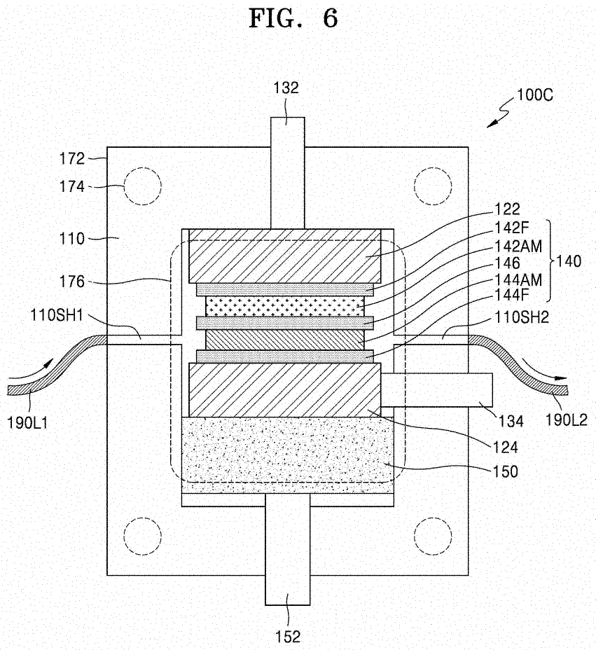

Although not shown, the cathode active material 142AM, the separator 146, and the anode active material 144AM may be soaked in an electrolyte. In some embodiments, to replenish an electrolyte consumed by repeating charging and discharging stages, as described below with reference to FIGS. 6 through 8, the lower housing 110 may further have supply line openings 110SH1 and 110SH2 formed therein to be supplied with an electrolyte from external supply lines 190L1 and 190L2. Also, at least one of the first electrode base portion 122 and the second electrode base portion 124 may further include a plurality of openings 122SH or a trench 122SL through which the electrolyte may pass.

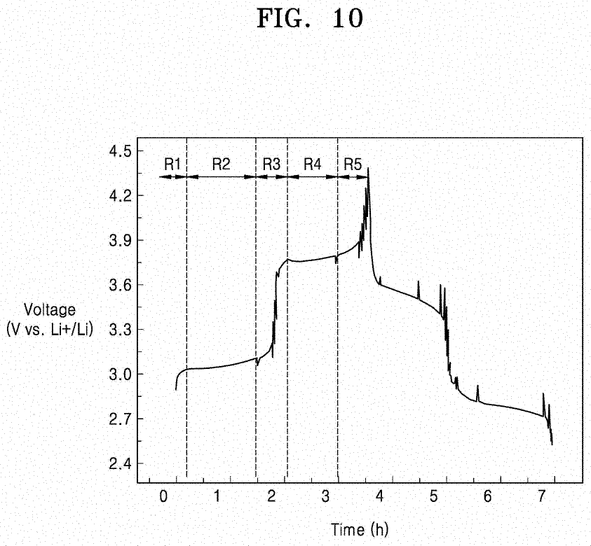

The cathode current collector 142F may include a conductive material and may be a thin conductive foil or a thin conductive mesh. For example, the cathode current collector 142F may include aluminum, nickel, copper, gold, or an alloy thereof. The cathode active material 142AM may include a material capable of reversibly intercalating/deintercalating lithium ions. The cathode active material 142AM may be an active material for analyzing phase change characteristics according to charging and discharging via the optical analysis unit 10 and the electrochemical analysis unit 20. In example embodiments, the cathode active material 43M may include a carboorganic-based cathode active material, a lithium phosphate-based cathode active material having an olivine structure, a vanadium oxide-based cathode active material, layered lithium metal oxides, a lithium manganese oxide-based cathode active material having a spinel structure, a sulfur-based cathode active material, or the like. For example, the result of analyzing, via the in-situ optical measurement system 1, electrochemical performance and phase change characteristics of the battery stack 140 using dimethyl phenazine as the cathode active material 142AM will be described in detail with reference to FIGS. 10 through 13B.

Although not shown, the cathode active material 142AM may further include a binder or a conductive material inside. The binder may attach particles of the cathode active material 142AM to each other and attach the cathode active material 142AM to the cathode current collector 142F. The conductive material may provide electrical conductivity to the cathode active material 142AM.

The anode current collector 144F may include a conductive material and may be a thin conductive foil or a thin conductive mesh. For example, the anode current collector 144F may include copper, nickel, aluminum, gold, or an alloy thereof. The anode active material 144AM may include a material capable of reversibly intercalating/deintercalating lithium ions. The anode active material 144AM may be an active material for analyzing phase change characteristics according to charging and discharging via the optical analysis unit 10 and the electrochemical analysis unit 20. In example embodiments, the anode active material 144AM may include a carbon-based anode active material, a graphite-based anode active material, a silicon-based anode active material, a tin-based anode active material, a composite anode active material, a lithium metal anode active material, or the like.

Although not shown, the anode active material 144AM may further include a binder or a conductive material inside. The binder may attach particles of the anode active material 144AM to each other and attach the anode active material 144AM to the anode current collector 144F. The conductive material may provide electrical conductivity to the anode active material 144AM.

The separator 146 may have porosity and may be configured as a single layer or a multilayer of two or more layers. The separator 146 may include a polymer material, e.g., at least one of polyethylene-based polymers, polypropylene-based polymers, polyvinylidene fluoride-based polymers, polyolefin-based polymers, and the like.

The battery cell measurement module 100 may further include a fixing plate 150 that is arranged to be in contact with the second electrode base portion 124 within the battery cell accommodation space 110S. A pressing-fixing portion 152 may extend from the outside of the lower housing 110 to the inside of the fixing plate 150 to be connected to the fixing plate 150. For example, the pressing-fixing portion 152 may move the fixing plate 150 in the first direction (the direction parallel to the upper surface of the transparent window 176) in a screw method, and the first electrode base portion 122, the battery stack 140, and the second electrode base portion 124 may be attached to one another by a preset compression force via the fixing plate 150.

In general, in a case of commercial battery cells in which a battery stack is arranged in a cylindrical or rectangular metal case or a coin cell in which a battery stack is arranged in a coin-type metal container, a cathode active material, a separator, and an anode active material in the battery stack may be closely arranged, and the total resistance of a commercial battery cell or a coin cell may be relatively low. When the incidental resistance of a battery cell or a coin cell, such as the resistance between a current collector and an active material or the resistance between a current collector and an external connection portion, is high, the total resistance of the battery cell or the coin cell may increase. In this case, the deviation between a potential difference (voltage) applied between a cathode active material and an anode active material and a potential difference (voltage) applied between a cathode terminal and an anode terminal of the battery cell may increase.

According to the present disclosure, the first electrode base portion 122, the battery stack 140, and the second electrode base portion 124 may be closely fixed via the fixing plate 150 and the pressing-fixing portion 152, and the resistance of the battery cell measurement module 100 may decrease. As the resistance of the battery cell measurement module 100 decreases, desired electrochemical tests may be performed under various current conditions (e.g., in charging and discharging at a high current rate), or the deviation between an electrochemical behavior in a commercial battery cell and an electrochemical behavior in the battery cell measurement module 100 may decrease (i.e., the electrochemical behavior in the commercial battery cell may be precisely simulated).

The upper cover 172 may include a metal or insulating material having rigidity. For example, the upper cover 172 may be formed of an SUS material to prevent corrosion but is not limited thereto. The cover fixing portion 174 may be a fixing portion capable of screwing but is not limited thereto. The transparent window 176 may be formed of a transparent insulating material. For example, the transparent window 176 may include quartz or beryllium glass. Although not shown, the transparent window 176 may further include a sealing member, such as an o-ring, formed at an edge portion thereof.

As shown as an example in FIG. 3, the cathode current collector 142F, the cathode active material 142AM, the separator 146, the anode active material 144AM, and the anode current collector 144F may be arranged to all face the transparent window 176. For example, the cathode active material 142AM may have a first thickness in a direction perpendicular to the upper surface of the cathode current collector 142F (e.g., the first direction (Y direction), the anode active material 144AM may have a second thickness in a direction perpendicular to the upper surface of the anode current collector 144F (e.g., the first direction (Y direction), and the entire first thickness of the cathode active material 142AM and the entire second thickness of the anode active material 144AM may be observed via the transparent window 176.

According to the example embodiments described above, as the cathode current collector 142F, the cathode active material 142AM, the separator 146, the anode active material 144AM, and the anode current collector 144F of the battery stack 140 are stacked in the battery cell measurement module 100 in a direction parallel to the transparent window 176, the cathode current collector 142F, the cathode active material 142AM, the separator 146, the anode active material 144AM, and the anode current collector 144F may be simultaneously observed or measured. In particular, the composition or image of the material at the fixed position may be continuously observed in the thickness direction of the cathode active material 142A or the thickness direction of the anode active material 144AM. Also, movement and the like of the interface between the cathode active material 142AM and the cathode current collector 142F adjacent thereto or the interface between the anode active material 144AM and the anode current collector 144F adjacent thereto may be simultaneously observed. Accordingly, an electrochemical behavior of the battery stack 140 occurring in charging and discharging stages for the battery stack 140 may be precisely measured or analyzed.

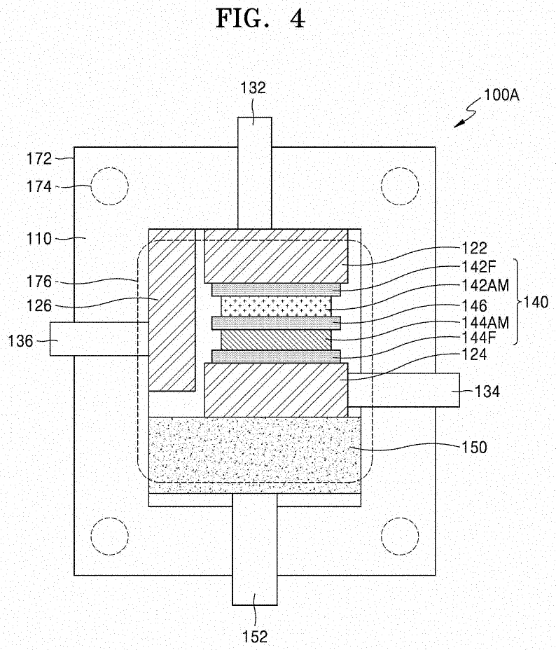

FIG. 4 is a plan view illustrating a battery cell measurement module 100A according to example embodiments. The same reference numerals in FIG. 4 as those in FIGS. 1 through 3 denote the same elements.

Referring to FIG. 4, the battery cell measurement module 100A may further include a third electrode base portion 126 arranged in a battery cell accommodation space 110S. The third electrode base portion 126 may be arranged on one side of a first electrode base portion 122, a battery stack 140, and a second electrode base portion 124. Also, the third electrode base portion 126 may be arranged adjacent to each of the first electrode base portion 122, the battery stack 140, and the second electrode base portion 124. A third electrode connection portion 136 may pass through a lower housing 110 to be electrically connected to the third electrode base portion 126. The battery cell measurement module 100A may correspond to a battery cell of a third electrode system.

The third electrode base portion 126 may further have a third electrode (not shown) arranged thereon. The third electrode may operates as a reference electrode that provides a reference voltage for a cathode active material 142AM and an anode active material 144AM. For example, the cathode active material 142AM may include dimethyl phenazine, the anode active material 144AM may include carbon, and the third electrode may include a lithium metal. In this case, voltage data of the cathode active material 142AM may be acquired with respect to the reference voltage by measuring a voltage between the first electrode base portion 122 and the third electrode base portion 126, and voltage data of the anode active material 144AM may be acquired with respect to the reference voltage by measuring a voltage between the second electrode base portion 124 and the third electrode base portion 126. Accordingly, an electrochemical behavior for each of the cathode active material 142AM and the anode active material 144AM may be comprehensively analyzed.

According to the example embodiments described above, a composition or image of a material at a fixed position may be continuously observed in a thickness direction of the cathode active material 142AM or a thickness direction of the anode active material 144AM. Also, movement and the like of an interface between the cathode active material 142AM and a cathode current collector 142F adjacent thereto or an interface between the anode active material 144AM and an anode current collector 144F adjacent thereto may be simultaneously observed. Therefore, an electrochemical behavior of the battery stack 140 occurring in charging and discharging stages for the battery stack 140 may be precisely measured or analyzed. Also, as the third electrode base portion 136 that operates as the reference electrode is further included, an electrochemical behavior for each of the cathode active material 142AM and the anode active material 144AM may be comprehensively analyzed.

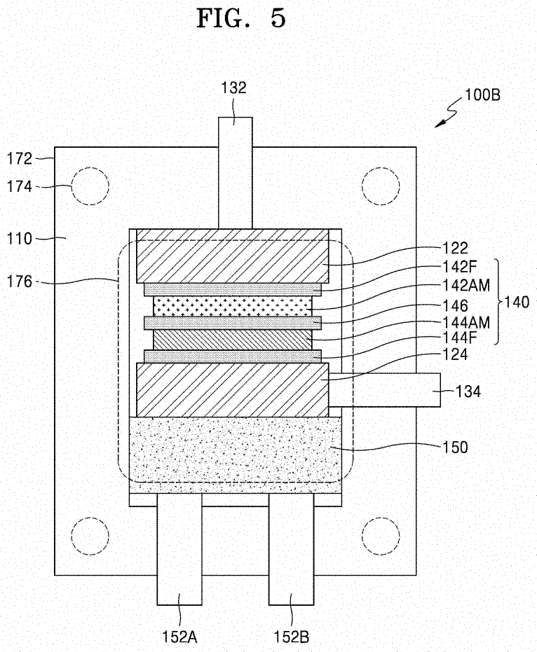

FIG. 5 is a plan view illustrating a battery cell measurement module 100B according to example embodiments. The same reference numerals in FIG. 5 as those in FIGS. 1 through 4 denote the same elements.

Referring to FIG. 5, the battery cell measurement module 100B may include a plurality of pressing-fixing portions 152A and 152B. The plurality of pressing-fixing portions 152A and 152B may move a fixing plate 150 in a first direction (a direction parallel to a transparent window 176). Also, a first electrode base portion 122, a battery stack 140, and a second electrode base portion 124 may be attached to one another by a preset compression force via the fixing plate 150 that is moved by the plurality of pressing-fixing portions 152A and 152B.

The plurality of pressing-fixing portions 152A and 152B may be spaced apart from each other to move the fixing plate 150. Therefore, a pushing force may be evenly distributed and applied to the fixing plate 150. Accordingly, damage to the battery stack 140, such as peeling, puncturing, or short-circuiting of a cathode active material 142AM or an anode active material 144AM may be prevented when the pushing force is applied to a local region of the battery stack 140.

FIG. 5 illustrates that two pressing-fixing portions 152A and 152B are spaced apart from each other, but the number and arrangement of the pressing-fixing portions 152A and 152B are not limited thereto.

According to example embodiments, the first electrode base portion 122, the battery stack 140, and the second electrode base portion 124 may be closely fixed via the fixing plate 150 and the plurality of pressing-fixing portions 152A and 152B, and the resistance of the battery cell measurement module 100B may decrease. As the resistance of the battery cell measurement module 100B decreases, desired electrochemical tests may be performed under various current conditions, or an electrochemical behavior in a commercial battery cell may be precisely simulated. Also, the damage to the battery stack 140, such as peeling, puncturing, or short-circuiting of the cathode active material 142AM or the anode active material 144AM may be prevented when the pushing force is applied to the local region of the battery stack 140.

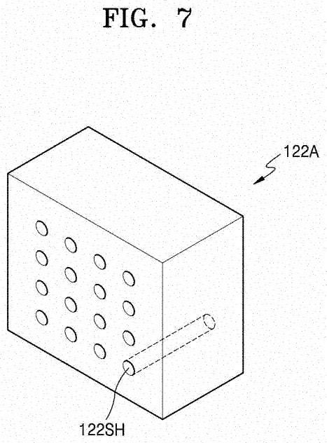

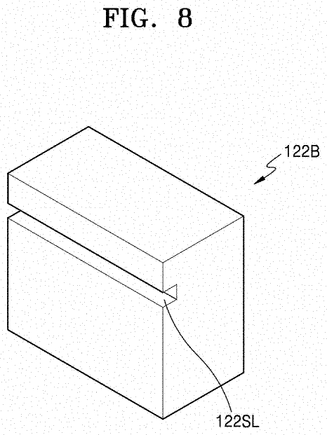

FIG. 6 is a plan view illustrating a battery cell measurement module 100C according to example embodiments. FIG. 7 is a perspective view illustrating a first electrode base portion 122A that may be used instead of a first electrode base portion 122 included in the battery cell measurement module 100C. FIG. 8 is a perspective view illustrating a first electrode base portion 122B that may be used instead of the first electrode base portion 122 included in the battery cell measurement module 100C. The same reference numerals in FIGS. 6 through 8 as those in FIGS. 1 through 5 denote the same elements.

Referring to FIGS. 6 through 8, a lower housing 110 may include supply line openings 110SH1 and 110SH2 that are in communication with a battery cell accommodation space 110S. For example, the first supply line opening 110SH1 may pass through a left side of the lower housing 110, and the second supply line opening 110SH2 may pass through a right side of the lower housing 110. Unlike the embodiment shown in FIG. 6, both the first supply line opening 110SH1 and the second supply line opening 110SH2 may be spaced apart from each other to pass through one side of the lower housing 110 (e.g., the left side or the right side).

Supply lines 190L1 and 190L2 may be respectively connected to the supply line openings 110SH1 and 110SH2. An electrolyte may be replenished from an external electrolyte supply source (not shown) into the battery cell accommodation space 110S via the supply line openings 110SH1 and 110SH by passing through the supply lines 190L1 and 190L2. For example, as indicated by arrows in FIG. 6, the electrolyte may be supplied from the first supply line 190SL1 into the battery cell accommodation space 110S, and the electrolyte may be discharged from the inside of the battery cell accommodation space 110S via the second supply line 190SL2.

As shown in FIG. 7, the first electrode base portion 122A may include a plurality of openings 122SH via which an electrolyte may pass. The plurality of openings 122SH may pass through the first electrode base portion 122A and may be arranged at the appropriate number and interval such that the electrolyte which is replenished into the battery cell accommodation space 110S may be sufficiently diffused through the first electrode base portion 122A to the cathode active material 142AM, the separator 146, and the anode active material 144AM.

As shown in FIG. 8, the first electrode base portion 122B may include the trench 122SL via which an electrolyte may pass. The trench 122SL may extend along the entire length of the first electrode base portion 122B in a direction parallel to the upper surface of the first electrode base portion 122B (e.g., an X direction). The trench 122SL may be arranged at the appropriate width, number, and interval such that an electrolyte replenished into the battery cell accommodation space 110S may be sufficiently diffused through the first electrode base portion 122B to the cathode active material 142AM, the separator 146, and the anode active material 144AM.

Although not shown, like the first electrode base portions 122A and 122B, the second electrode base portion 122 may also include the plurality of openings 122SH or the trench 122SL.

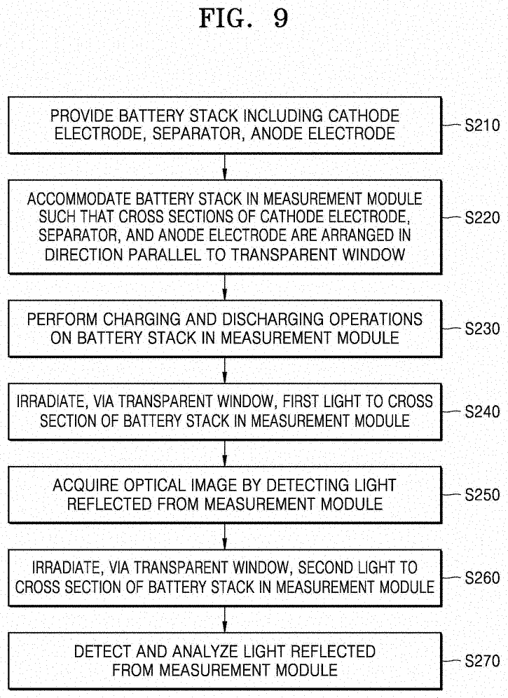

FIG. 9 is a flowchart illustrating an in-situ optical and electrochemical analysis method according to example embodiments.

Referring to FIG. 9, in operation S210, a battery stack including a cathode electrode, a separator, and an anode electrode are provided.

The battery stack 140 may include a cathode electrode that is formed by coating and drying the cathode active material 142AM on the cathode current collector 142F, an anode electrode that is formed by coating and drying the anode active material 144AM on the anode current collector 144F, and the separator 146 between the cathode electrode and the anode electrode. The battery stack 140 may be soaked in an electrolyte for a certain time.

In operation S220, the battery stack may be accommodated in a battery cell measurement module such that the cross sections of the cathode electrode, the separator, and the anode electrode are arranged in a direction parallel to a transparent window.

The battery stack 140 may be temporarily fixed between the first electrode base portion 122 and the second electrode base portion 124, and the battery stack 140, the first electrode base portion 122, and the second electrode base portion 124 in this state may be referred to as a “battery cell block.” The battery cell block may be accommodated in the battery cell accommodation space 110S such that the first electrode base portion 122, the battery stack 140, and the second electrode base portion 124 may be sequentially arranged in the first direction (Y direction).

The battery cell block may be fixed to an inner wall of the lower housing 110 via the fixing plate 150 and the pressing-fixing portion 152. The upper cover 172 may be fixed to the lower housing 110 to assemble the battery cell measurement module 100 such that the transparent window 176 may overlap a side of the battery stack 140 to simultaneously observe, via the transparent window 176, the side of the battery stack 140, i.e., sides of the cathode current collector 142F, the cathode active material 142AM, the separator 146, the anode active material 144AM, and the anode current collector 144F.

In operation S230, charging and discharging operations may be performed on the battery stack in the battery cell measurement module.

Information about the capacity, voltage, current, and time of the battery stack 140 may be obtained via the electrochemical analysis unit 20 connected to the battery cell measurement module 100. For example, a unit charging step or a unit discharging step using a preset current density may be performed on the battery stack 140 via the electrochemical analysis unit 20.

In operation S240, first light may be irradiated, via the transparent window, to the cross section of the battery stack in the battery cell measurement module.

In operation S250, an optical image may be acquired by detecting light reflected (light scattered) from the battery cell measurement module.

In operation S260, second light may be irradiated, via the transparent window, to the cross section of the battery stack in the battery cell measurement module. The second light may be light having a wavelength that is different from that of the first light.

In operation S270, the light reflected (or the light scattered) from the battery cell measurement module may be detected and analyzed.

For example, when a voltage of the battery stack 140 reaches a preset first measurement voltage, operation S240 of irradiating the first light, operation S250 of acquiring the optical image by detecting the scattered light of the first light, operation S260 of irradiating the second light, and operation S270 of detecting and analyzing the scattered light of the second light may be sequentially performed. Operations S240 through S270 may be referred to as one light measurement cycle. The electrochemical analysis unit 20 may be programmed such that a constant voltage is maintained in the battery stack 140 or the flow of a current is stopped during the light measurement cycle.

For example, operation S260 of irradiating the second light and operation S270 of detecting and analyzing the scattered light of the second light may be operations of acquiring a Raman shift characteristic or a PL characteristic.

In example embodiments, in operation S260 of irradiating the second light, the second light may be continuously irradiated by a first scan width in a thickness direction of the battery stack 140 observed via the transparent window 176. For example, the first scan width may overlap each of a portion of the cathode active material 142AM, the separator 146 adjacent thereto, and a portion of the anode active material 144AM.

In other embodiments, in operation S260 of irradiating the second light, the second light may be irradiated sequentially to a plurality of measurement positions on a side of the battery stack 140 observed via the transparent window 176. For example, the plurality of measurement positions may overlap each of a portion of the cathode active material 142AM, the separator adjacent thereto, and a portion of the anode active material 144AM.

Operations S210 through S270 may be repeated.

In detail, after one light measurement cycle is performed, a unit charging step or a unit discharging step using a preset current density may be performed again on the battery cell 140 via the electrochemical analysis unit 20. In a second light measurement cycle, the second light may be irradiated to the same measurement position as the measurement position to which the second light is irradiated in a first light measurement cycle. Accordingly, Raman shift information of the cathode active material 142AM and/or the anode active material 144AM arranged at the same measurement position over time or according to a change in a voltage may be provided. Therefore, phase change characteristics, interfacial characteristics, and/or crystal structure of the cathode active material 142AM and/or the anode active material 144AM may be precisely analyzed.

For example, sequentially performing operations S210 through S270 may constitute a unit charging step or a unit discharging step. An in-situ optical and electrochemical analysis method according to example embodiments may include a total of five to several tens of unit charging steps and/or a total of five to several tens of unit discharging steps.

In general, in an existing in-situ electrochemical cell, a structure in which a cathode active material and an anode active material are stacked with a separator therebetween is arranged in a coin-type cell having an opening formed in the upper surface thereof, and merely the surface of the cathode active material is observed via the opening or the merely the surface of the anode active material is observed via the opening. In particular, the surface observable via the opening may be the surface arranged on the uppermost portion of the coin-type cell or the surface of an anode portion from which a corresponding cathode portion is removed (or the surface of the cathode portion from which the corresponding anode portion is removed). Accordingly, an electrochemical behavior of an active material on the surface observable via the opening may be significantly different from an electrochemical behavior occurring in an internal region of the coin-type cell, and thus, precise analysis of an electrochemical behavior may not be easily performed.

However, according to the present disclosure, as the cathode current collector 142F, the cathode active material 142AM, the separator 146, the anode active material 144AM, and the anode current collector 144F of the battery stack 140 are stacked in a direction parallel to the transparent window 176, the cathode current collector 142F, the cathode active material 142AM, the separator 146, the anode active material 144AM, and the anode current collector 144F may be simultaneously observed or measured. In particular, a composition or image of a material at a fixed position may be continuously observed in a thickness direction of the cathode active material 142AM or a thickness direction of the anode active material 144AM. Also, movement and the like of an interface between the cathode active material 142AM and the cathode current collector 142F adjacent thereto or an interface between the anode active material 144AM and the anode current collector 144F adjacent thereto may be simultaneously observed. Accordingly, an electrochemical behavior of the battery stack 140 occurring in charging and discharging stages for the battery stack 140 may be precisely measured or analyzed.

Hereinafter, the result of analysis acquired by performing an in-situ optical and electrochemical analysis method according to example embodiments by using a battery cell measurement module according to example embodiments will be described with reference to FIGS. 10 through 13B. FIGS. 10 through 13B illustrate an in-situ optical and electrochemical analysis method performed on a battery stack which uses, as a cathode active material, dimethyl phenazine (DMPZ) that is one of carboorganic cathode materials, and uses lithium metal as an anode active material.

FIG. 10 is a graph illustrating a voltage profile in one-time charging and one-time discharging for a DMPZ cathode active material. FIG. 10 illustrates a voltage of a cathode active material obtained in a constant current mode.

Referring to FIG. 10, DMPZ that is a carboorganic cathode material may show two plateau regions R2 and R4. In detail, after charging starts, a first region R1 where a voltage increases, a second region R2 having a constant voltage section at about 3.0 V to about 3.1 V, a third region R3 where the voltage increases, a fourth region R4 having a constant voltage section at about 3.75 V to about 3.85 V, and a fifth region R5 where the voltage increases are shown.

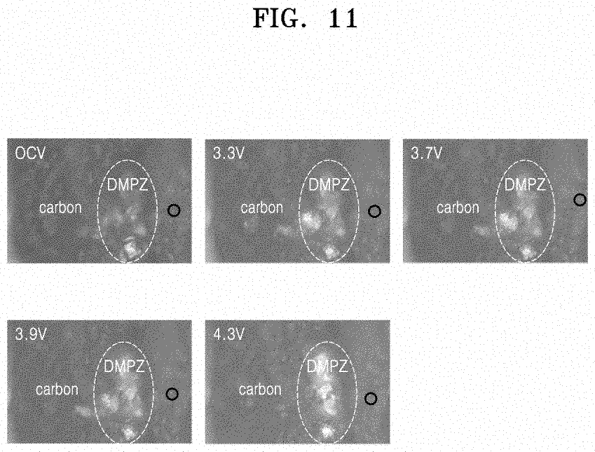

FIG. 11 illustrates optical images of a cathode active material at different voltages during one-time charging. FIG. 11 shows optical images of a DMPZ cathode active material obtained from scattering of first light at an open-circuit voltage (OCV), 3.3 V, 3.7 V, 3.9 V, and 4.3V.

Referring to FIG. 11, a DMPZ-rich region where DMPZ particles are locally aggregated and arranged is observed at the open-circuit voltage (OCV) (i.e., in a voltage region corresponding to the first region R1 in FIG. 9). After a first plateau passes, the amount of DMPZ particles arranged in the DMPZ-rich region increases at 3.3 V (i.e., in a voltage region corresponding to a starting point of the third region R3 in FIG. 9), and this increase may occur because the DMPZ particles are precipitated on the surface. A morphology of the DMPZ-rich region is not significantly changed at 3.7 V (i.e., in a voltage region corresponding to an end point of the third region R3 in FIG. 9). Also, after a second plateau passes, a small amount of the DMPZ particles in the DMPZ-rich region is observed at 3.9 V (in a voltage region corresponding to the fifth region R5 in FIG. 9). This may occur because DMPZ is eluted into an electrolyte in a second plateau stage.

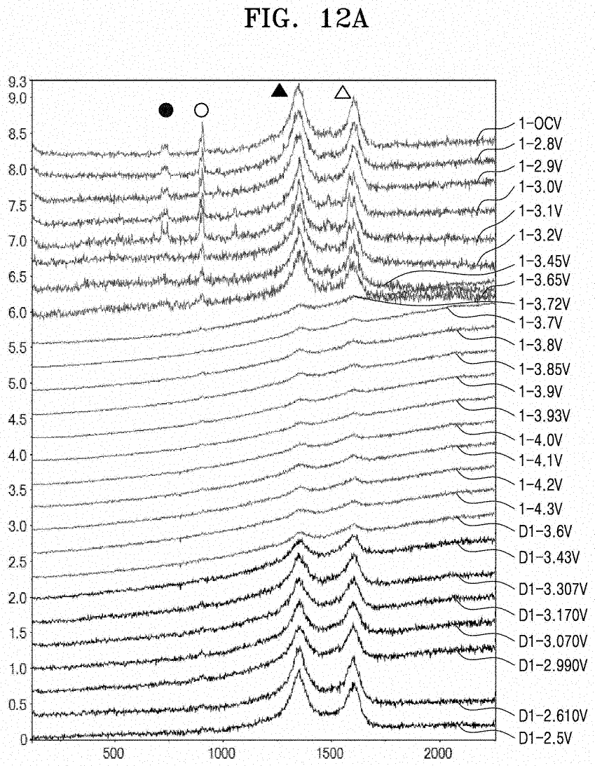

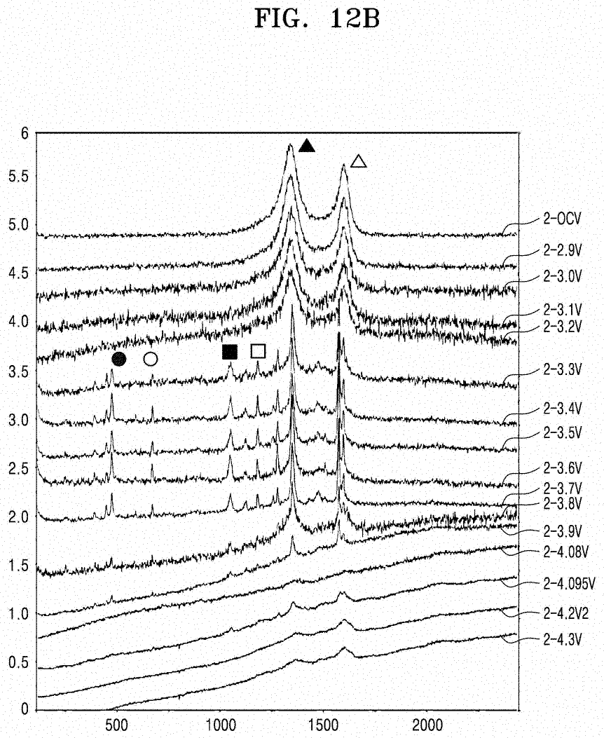

FIGS. 12A and 12B are Raman shift graphs at different voltages during one-time charging and one-time discharging in a first portion and a second portion of a cathode active material.

Referring to FIG. 12A, in the first portion, four peaks including a first peak (denoted with a shaded circle in FIG. 12A) and a second peak (denoted with a non-shaded circle in FIG. 12A) derived from DMPZ, a third peak (denoted with a shaded triangle in FIG. 12A) and a fourth peak (denoted with a non-shaded triangle in FIG. 12A) derived from carbon are observed from an open-circuit voltage (OCV) to 3.1 V in an initial charging stage. The first peak and the second peak are not observed from 3.45 V, and the intensity of the third peak and the fourth peak significantly decreases from 3.72 V. When a discharging stage starts, the third peak and the fourth peak (Δ) starts to be observed again, but the first peak and the second peak are not observed. This may occur because DMPZ is eluted into an electrolyte in a region of 3.1 V that is a first plateau section, and thus moves to another portion on an electrode from the first portion where DMPZ particles are arranged in the initial stage charging.

Referring to FIG. 12B, in the second portion, merely the third peak (denoted with a shaded triangle in FIG. 12B) and the fourth peak (denoted with a non-shaded triangle in FIG. 12B) derived from carbon are observed from the open-circuit voltage (OCV) to 3.2 V in the initial charging stage. In a region from 3.3 V to 3.7 V, i.e., in a voltage rise section (a voltage region corresponding to the third region R3 in FIG. 9) after a first plateau section passes, the first peak (denoted with a shaded circle in FIG. 12B), the second peak (denoted with a non-shaded circle in FIG. 12B), a fifth peak (denoted with a shaded square in FIG. 12B), and a sixth peak (denoted with a non-shaded square in FIG. 12B) derived from DMPZ are observed. This may occur because DMPZ is not arranged in the second portion in the initial charging stage, but DMPZ particles which are eluted into an electrolyte move to and adsorb on the second portion by passing through 3.1 V that is the first plateau section.

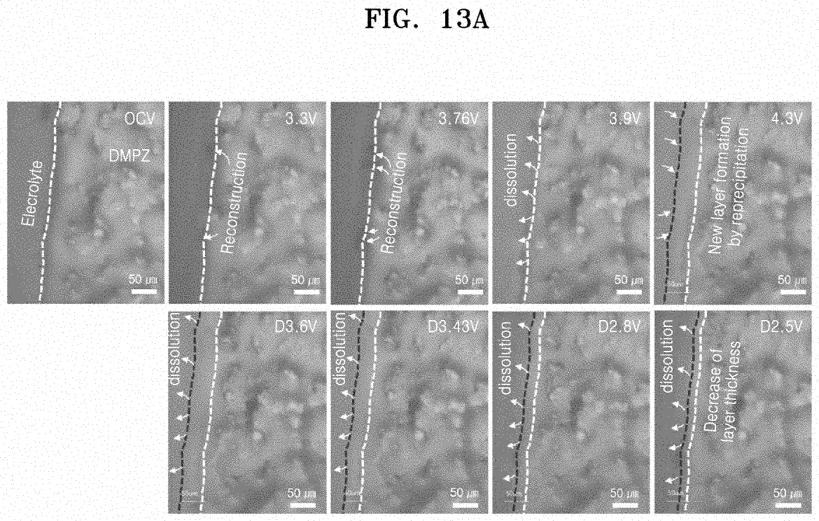

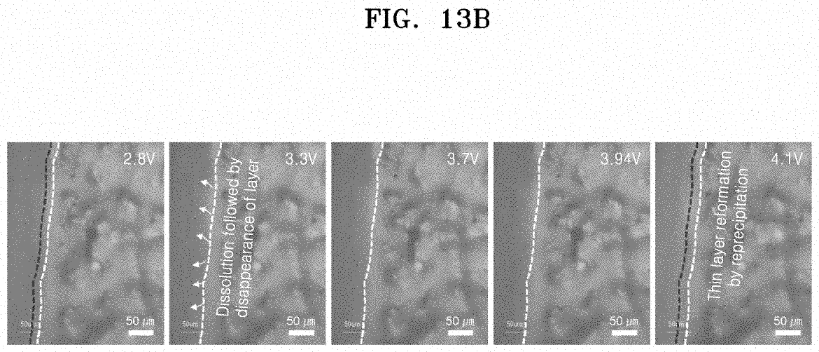

FIG. 13A illustrates optical images of a cathode active material according to voltages in each of a first charging cycle and a first discharging cycle. FIG. 13B illustrates optical images of a cathode active material according to voltages in a second charging cycle.

Referring to FIG. 13A, in a first charging cycle, when a charging stage is performed from an initial charging stage to 3.76V through 3.3 V, surface precipitation of DMPZ occurs at an interface between a DMPZ cathode active material and an electrolyte (or a separator). In other words, DMPZ that is eluted from a DMPZ-rich region into an electrolyte is precipitated at an interface between a cathode active material and the electrolyte. DMPZ is dissolved again at 3.9 V that is a section occurring after a second plateau passes, and thus, the interface between the cathode active material and the electrolyte recedes in a direction of the cathode active material. At 4.3 V, a new layer is formed at the interface of the cathode active material due to reprecipitation of DMPZ, and the thickness of the cathode active material also increases.

In a first discharging cycle, as the voltage decreases to 3.6 V, 3.43 V, 2.8 V, and 2.5 V, the interface between the cathode active material and the electrolyte gradually recedes in the direction of the cathode active material, and the thickness of the formed layer decreases. This may occur because the dissolution of DMPZ occurs continuously.

Referring to FIG. 13B, in a second charging cycle, a layer formed by the dissolution of DMPZ into an electrolyte is observed to disappear at 3.3 V. Also, at 4.1 V, a new layer is observed to be re-formed at an interface of a cathode active material by the reprecipitation of DMPZ. However, compared to the first charging cycle, the degree of interfacial movement due to the dissolution of DMPZ is insignificant, and the thickness of the new layer formed by the reprecipitation of DMPZ is also not great.

As described above in detail with reference to FIGS. 10 through 13B, via a battery cell measurement module and an in-situ optical and electrochemical analysis method according to the present disclosure, an electrochemical behavior and an interfacial characteristic of a carboorganic-based cathode active material including DMPZ may be observed. Therefore, various approaches for performance improvement and commercialization of the carboorganic-based cathode active material may be derived. The present disclosure may be applied to comprehensive analysis of electrochemical behaviors, such as identification of electrochemical reactions of not only carboorganic-based cathode active materials, but also other cathode active materials and anode active materials, observation of a change in crystalline phase or crystal structure, analysis of a reaction rate in a local region, observation of interfacial movement of an active material, and observation of a change in local thickness of the active material.

While the present disclosure has been particularly shown and described with reference to example embodiments thereof, it will be understood by those skilled in the art that various changes in form and details may be made therein without departing from the spirit and scope of the disclosure as defined by the appended claims.

Acknowledgement

This research was supported by the Basic Science Research Program through the National Research Foundation of Korea funded by the Ministry of Science and ICT (NRF-2017M3A7B4049176).

This work was supported by the Korea Basic Science Institute (KBSI) grant No. T38606.

This work was supported by the National Research Foundation of Korea (NRF) grant funded by Korea government (MSIT)(2018R1A5A 1025224).

This research was supported by Creative Materials Discovery Program through the National Research Foundation of Korea (NRF) funded by the Ministry of Science, ICT and Future Planning (NRF-2017M3D1A1039561).

1. A battery cell measurement module for in-situ optical and electrochemical analysis comprising:
a lower housing including a battery cell accommodation space therein;
an upper cover that is detachably attached to the lower housing and provided with a transparent window; and
a battery cell block that is arranged in the battery cell accommodation space and includes:
a first electrode base portion,
a second electrode base portion, and
a battery stack arranged between the first electrode base portion and the second electrode base portion, wherein
the first electrode base portion, the battery stack, and the second electrode base portion are sequentially arranged in a first direction parallel to an upper surface of the transparent window such that a thickness direction of the battery stack is arranged parallel to the upper surface of the transparent window.

2. The battery cell measurement module of claim 1, wherein the battery stack comprises:
a cathode current collector having a cathode active material attached thereto;
an anode current collector having an anode active material attached thereto; and
a separator arranged between the cathode active material and the anode active material, wherein
the battery cell block is arranged such that the cathode current collector, the cathode active material, the separator, the anode active material, and the anode current collector all face the transparent window.

3. The battery cell measurement module of claim 2, wherein
the cathode active material has a first thickness in a direction perpendicular to an upper surface of the cathode current collector,
the anode active material has a second thickness in a direction perpendicular to an upper surface of the anode current collector, and
the battery cell block is arranged such that the entire first thickness of the cathode active material and the entire second thickness of the anode active material are observed via the transparent window.

4. The battery cell measurement module of claim 2, further comprising:
a third electrode base portion that is arranged in the battery cell accommodation space, and
the third electrode base is arranged on one side of the first electrode base portion, the battery stack, and the second electrode base portion to be located adjacent to all of the first electrode base portion, the battery stack, and the second electrode base portion, wherein
the third electrode base portion operates as a reference electrode that provides a reference voltage for the cathode active material and the anode active material.

5. The battery cell measurement module of claim 1, wherein
the lower housing further comprises a supply line opening configured to supply an electrolyte from an external supply portion into the battery cell accommodation space, and
the first electrode base portion is configured to comprise at least one of:
a plurality of openings that pass through the first electrode base portion; and
a trench that extends along the entire length of the first electrode base portion in a direction parallel to an upper surface of the first electrode base portion, and
allow the electrolyte to reach the battery stack via at least one of the plurality of openings and the trench.

6. An in-situ optical and electrochemical analysis method using a battery cell measurement module that includes a lower housing including a battery cell accommodation space therein, an upper cover that is detachably attached to the lower housing and provided with a transparent window, and a battery cell block arranged in the battery cell accommodation space, the in-situ optical and electrochemical analysis method comprising:
sequentially arranging a first electrode base portion, a battery stack, and a second electrode base portion included in the battery cell block, in a first direction parallel to the upper surface of the transparent window, and
performing charging and discharging operations on the battery cell measurement module; and
performing, a plurality of times, a light measurement cycle on the battery cell measurement module, wherein
the light measurement cycle comprises:
irradiating first light to a first portion of the battery stack observed via the transparent window;
detecting the first light scattered from the battery stack;
irradiating, to the first portion of the battery stack observed via the transparent window, second light having a second wavelength that is different than a first wavelength of the first light; and
detecting the second light scattered from the battery stack.

7. The in-situ optical and electrochemical analysis method of claim 6, wherein the irradiating of the second light comprises continuously irradiating the second light by a first scan width in a thickness direction of the battery stack observed via the transparent window.

8. The battery cell measurement module of claim 7, wherein:
the battery stack comprises:
a cathode current collector having a cathode active material attached thereto;
an anode current collector having an anode active material attached thereto; and
a separator arranged between the cathode active material and the anode active material, wherein
the battery cell block is arranged such that the cathode current collector, the cathode active material, the separator, the anode active material, and the anode current collector all face the transparent window, and
the irradiating of the second light comprises at least one of:
continuously irradiating the second light by the first scan width in a thickness direction of the cathode active material observed via the transparent window; and
continuously irradiating the second light by the first scan width in a thickness direction of the anode active material observed via the transparent window.
